(19) United States
(12) Patent Application Publication
(10) Pub. No.: US 2007/0077778 A1
(43) Pub. Date: Apr. 5, 2007

(54) Method of forming low dielectric constant layer

(75) Inventors: Ce Ma, Cary, NC (US); Qing Min Wang, Edison, NJ (US); Patrick J. Helly, Valley Center, CA (US); Graham McFarlane, Murrieta, CA (US)

Correspondence Address: THE BOC GROUP, INC., 575 MOUNTAIN AVENUE, MURRAY HILL, NJ, 07974-2064, US

(73) Assignee: The BOC Group, Inc.

(21) Appl. No.: 11/243,157

(22) Filed: Oct. 4, 2005

(51) Int. Cl. H01L 21/31

(52) U.S. Cl. 438/778; 438/780; 438/790

(57) ABSTRACT

Dielectric layers having a low dielectric constant are fabricated by using an asymmetric organocyclosiloxane as a precursor gas. The carbon content of the deposited layer is reduced to less than about 50 percent by use an oxidizing agent, a silicon containing compound, or a combination thereof.

### TECHNICAL FIELD

The present invention relates generally to a method of forming a low dielectric constant layer and particularly to such a method of forming a low k dielectric layer using asymmetric organocyclosiloxane in combination with at least one compound to reduce the carbon content of the formed dielectric layer. Further, the present invention relates to low k dielectric layers having reduced carbon content.

### BACKGROUND OF THE INVENTION

As semiconductor integrated circuits continue to increase the number of included devices, the devices within the circuit continue to have smaller feature sizes and smaller spaces between the devices and the features. The larger number of devices in integrated circuits requires that the metallizations interconnecting the devices be placed on several levels with dielectric layers between the metallizations. The dielectric constant, k, of the dielectric layer is critical for several reasons, including, the dielectric constant, k, contributes to the RC time constant, where R is the resistance and C is the capacitance which is proportional to k; that ultimately determines device and circuit speed. Further, a lower dielectric constant, for given device dimensions and spacing, reduces cross talk between adjacent metal lines whether they are on the same or adjacent metallization levels. A lower dielectric constant thus permits closer feature spacing and more devices per unit area on the integrated circuit as well as thinner dielectric layers.

The most widely used dielectric at present is silicon dioxide, SiO₂, usually deposited by a vapor phase deposition method, wherein a silicon containing precursor gas is oxidized and silicon oxide is formed on the substrate. Typical precursor gases include silane, disilane, and tetraethyloxysilane. Typical vapor phase deposition methods include chemical vapor deposition (CVD), plasma enhanced CVD (PECVD), and high density plasma CVD (HDPCVD). The dielectric constant of the vapor deposited SiO₂ is approximately 4.2. While this value of the dielectric constant is adequate for many applications, as device dimensions features shrink to less than 200 nm, lower values will be required. The 2003 ITRS(International Technology Roadmap for Semiconductors) reports that low k dielectrics with a bulk k value less than 2.7 will be required for 107, 95 and 85 nm design features while a bulk k value less than 2.4 will be required for 76, 67 and 60 nm design features. Bulk k values less than 2.2 would be desirable.

The deposited dielectric layer must not only have a low dielectric constant, but must also meet the other material, electrical and reliability requirements necessary to survive the temperatures and other parameters encountered in integrated circuit processing. Additionally, the deposition must be rapid enough for commercial use. Several examples of methods for vapor deposition of low k dielectric layers known in the prior art are described below.

U.S. Pat. No. 6,475,564 describes a method for depositing a low dielectric constant dielectric layer using several precursor gases including a silicon containing compound, such as an organosilane, a compound containing peroxide bonding, and a substance that associates readily with the peroxide containing substance to yield a substance on the substrate. A dielectric constant of 2.8 is obtained with a deposition rate of 1.2 microns/minute. The deposited substance is a short chain polymer and a planar surface is formed.

U.S. Pat. No. 6,352,945 describes a method of depositing a silicone polymer layer with a micropore structure that results in a relatively low k dielectric constant for the layer. A silicon containing hydrocarbon having no more than two alkoxy groups is the precursor gas, and a silicone polymer having —SiR₂O— repeating units is formed by a plasma polymerization method. Dielectric constants of approximately 2.6 are obtained.

U.S. Pat. No. 6,287,989 describes a method of forming a short chain polymer by reacting a silicon containing precursor gas with a peroxide containing compound to form the short chain polymer. At the time of deposition, the polymer is liquid and forms a planar surface. Subsequently, the polymer is solidified with a heat treatment. Dielectric constants are not given.

United States Patent Application Publication 2002/0098714 describes fabrication of ultra low dielectric materials that are capable of withstanding the temperatures typically encountered in semiconductor processing. Two precursor gases are used with the first precursor gas being a molecule with a ring structure comprising Si, C, O, and H atoms, and the second precursor gas being an organic molecule having a ring structure. Additional gases may be used in the plasma reactor to stabilize the plasma and improve the uniformity of the dielectric. Dielectric constants below 2.0 are obtained using deposition conditions that result in pores within the dielectric material having diameters between 0.5 and 2.0 nm.

The following three references are assigned to the assignee of this application.

U.S. Pat. No. 6,440,876 describes the formation of low k dielectric layers using a cyclic siloxane precursor gas having a Si—O—C in ring structure. When the precursor gas is applied to the surface, it reacts with a ring opening polymerization to form a dielectric layer. Use of an oxidant and inert carrier gas is optional.

U.S. Pat. No. 6,649,540 uses a substituted organosilane precursor gas which is applied to the substrate surface where it reacts to form a dielectric layer. The necessary elements for forming the low k layer are Si, C, and H. Optionally, an oxidant such as O₂ or N₂O may be used to facilitate formation of the low k layer.

U.S. Pat. No. 6,572,923, incorporated herein by reference, describes a method of forming a low k dielectric film by applying an asymmetric organocyclosiloxane to the substrate surface where it reacts and forms a dielectric layer on the substrate surface. The deposition method may be either pyrolytic or plasma assisted. Optionally, an oxygen-containing precursor may also be used. Representative synthesis procedures are described in detail, as are the structures of the resulting molecules.

Although dielectric layers fabricated using the organocyclosiloxanes previously mentioned as precursor gases may have low dielectric constants, they have properties that may not be adequate for some applications. For example, vinylpentamethylcyclo-trisiloxane may be used as a precursor to form a dielectric layer with a suitably low dielectric constant but with a hardness that may not withstand typical semiconductor processing.

### SUMMARY OF THE INVENTION

The present invention provides a method for forming a dielectric layer including the steps of applying to the surface of a substrate an asymmetric organocyclosiloxane compound, and at least one compound to reduce the carbon content of the formed dielectric layer, to a substrate surface, wherein the asymmetric compound reacts with and deposits on the substrate surface to form a dielectric layer. The selected compound preferably is used in an amount sufficient to reduce the carbon content of the dielectric layer to less than about 50 atomic weight percent. The present invention further provides low k dielectric layers having carbon contents less than about 50 atomic weight percent.

### DETAILED DESCRIPTION

According to the present invention, a low k dielectric layer is formed using an asymmetric organocyclosiloxane compound as a precursor gas together with at least one compound present in a selected amount to reduce the carbon content of the dielectric layer. The additional compound is an oxidizing agent or a silicon containing material or a combination of both. The oxidizing agent or silicon containing material is present in an amount that yields dielectric layers having increased mechanical strength due to reduced carbon content. The dielectric layer is formed on a substrate, such as a silicon wafer, by any standard deposition technique, for example, a plasma enhanced chemical vapor deposition chamber or with a pyrolitic process.

The dielectric layer is formed by a reaction of the organocyclosiloxane that results in opening of the cyclic structure and polymerization onto the substrate surface. The present method allows for better control of both the organic content and the steric effect of the organic groups in the final dielectric layer. This is important because reduction of film density and the formation of micropores facilitate obtaining low dielectric constant layers. Preferred organocyclosiloxanes are asymmetric compounds having the chemical formula (—SiO—)ₙR₍₂ₙ₋ₘ₎R′ₘ where (—SiO—) is a cyclic siloxane ring; n is at least 3; R is an alkyl containing hydrocarbon from C1 to C7; R′ is an member selected from the group consisting of H, a vinyl group, and a cyclohexyl group; and m is at least 1. These compounds and methods for their preparation are described, as previously mentioned, in U.S. Pat. No. 6,572,923, wherein one example is the compound vinylpentamethylcyclotrisiloxane.

In accordance with the present invention, it was found that the strength of the deposited dielectric layer can be increased if the carbon content of the layer is decreased to a value below about 50 atomic weight percent. A carbon content in the range of 15 to 25 atomic weight percent is preferred. However, to obtain low dielectric constants, the micropore structure of the dielectric film must be retained, and therefore a simple reduction of the carbon content of the precursor gas will not suffice.

The present invention has found that low k dielectric layers exhibiting sufficient strength to withstand semiconductor processing operations, can be formed through the use of an additional compound which reduces the carbon content of the formed dielectric layer. In one embodiment of the present invention, the carbon content of the formed dielectric layer is reduced using an oxidizing agent in an amount calculated to reduce the carbon content to below 50 atomic weight percent and preferably in the range of 15 to 25 atomic weight percent. The oxidizing agent, in preferred embodiments, is selected from the group consisting of O₂, O₃, N₂O, and H₂O₂. The amount of carbon in the deposited layer without use of an oxidizing agent can be easily measured, and the required amount of oxidizing agent can then be calculated. An annealing step may be used to further reduce the carbon content, the amount of which can also be measured and then used in calculating the amount of oxidizing agent required to obtain the desired carbon content in the dielectric layer. Times and temperatures for the annealing step will be readily determined by those skilled in the art.

In a further embodiment of the present invention, a silicon-containing compound in included to facilitate reduction of the carbon content. Preferred silicon-containing compounds are selected from the group consisting of —SiH₄; MeSiH₃; MeSi(OMe)₃, Me₂Si(OEt)₂; Me₃Si(OEt); vinylSiMe₃; vinylSiMe₂H; vinylSiMeH₂; vinylSi(OMe)₃; hexamethylcyclotrisiloxane; trimethylcyclotrisiloxane; octamethylcyclotetrasiloxane; and tetramethylcyclotetrasiloxane. Additonally, asymmetric organocyclosiloxanes such as 1,3-divinyl-1,3,5-trimethylcyclotrisiloxane and 1,1-divinyl-3,3,5,5-tetramethylcyclotrisiloxane may be used. The amount of the silicon-containing compound used, can be calculated in a similar manner to that described above, to result in a carbon content of the formed dielectric layer of below 50 atomic weight percent and preferably in the range of 15 to 25 atomic weight percent.

A further option according to the present invention is to use both an oxidizing agent and a silicon-containing compound to reduce the carbon content of the formed dielectric layer. Similar calculations can be carried out to determine the amounts of each needed to achieve the desired results.

The dielectric layers of the present invention may be readily fabricated using conventional PECVD chambers together with the associated gas handling apparatus and control systems. Appropriate techniques for conveying the precursor and other gases to the reaction chamber, as well as pressures and powers will be readily selected based on the properties of the precursor and other gases such as moisture(water vapor), CO and CO₂. Alternatively, standard pyrolitic deposition methods may be used.

It is anticipated that other embodiments and variations of the present invention will become readily apparent to the skilled artisan in the light of the foregoing description and examples, and it is intended that such embodiments and variations likewise be included within the scope of the invention as set out in the appended claims.

What is claimed is:

1. A low k dielectric layer having a carbon content of less than about 50 atomic weight percent.

2. The dielectric layer of claim 1, wherein said carbon content is in the range of 15 to 25 atomic weight percent.

3. The dielectric layer of claim 1, wherein said layer comprises an asymmetric organocyclosiloxane compound.

4. The dielectric layer of claim 3, wherein said organocyclosiloxane has the chemical formula (—SiO—)ₙR₍₂ₙ₋ₘ₎R′ₘ where (—SiO—) is a cyclic siloxane ring; n is at least 3; R is an alkyl containing hydrocarbon from C1 to C7; R′ is an member selected from the group consisting of H, a vinyl group, and a cyclohexyl group; and m is at least 1.

5. A method of forming a low k dielectric layer comprising the steps of:
providing a substrate having a surface;
applying an asymmetric organocyclosiloxane compound along with at least one compound selected to reduce the carbon content of said dielectric layer, to said substrate surface; and
reacting said organocyclosiloxane compound with said substrate surface and depositing said dielectric layer on said substrate surface;
wherein said dielectric layer has a carbon content less than about 50 atomic weight percent.

6. The method according to claim 5, wherein said at least one compound is an oxidizing agent.

7. The method according to claim 6, wherein said oxidizing agent is selected from the group consisting of O₂, O₃, N₂O, and H₂O₂.

8. The method according to claim 5, wherein said at least one compound is a silicon containing compound.

9. The method according to claim 8, wherein said silicon containing compound is selected from the group consisting of SiH₄; MeSiH₃; MeSi(OMe)₃; Me₂Si(OEt)₂; Me₃Si(OEt); vinylSiMe₃; vinylSiMe₂H; vinylSiMeH₂; vinylSi(OMe)₃; hexamethylcyclotrisiloxane; trimethylcyclotrisiloxane; octamethylcyclotetrasiloxane; tetramethylcyclotetrasiloxane; 1,3-divinyl-1,3,5-trimethylcyclotrisiloxane and 1,1-divinyl-3,3,5,5-tetramethylcyclotrisiloxane.

10. The method according to claim 5, wherein said carbon content of said dielectric layer is in the range of 15 to 25 atomic weight percent.

11. The method according to claim 5, wherein said at least one compound comprises an oxidizing agent and a silicon containing compound.

12. The method according to claim 11, wherein said carbon content of said dielectric layer is in the range of 15 to 25 atomic weight percent.

13. The method according to claim 5, wherein said organocyclosiloxane has the chemical formula (—SiO—)ₙR₍₂ₙ₋ₘ₎R′ₘ where (—SiO—) is a cyclic siloxane ring; n is at least 3; R is an alkyl containing hydrocarbon from C1 to C7; R′ is a member selected from the group consisting of H, a vinyl group, and a cyclohexyl group; and m is at least 1.

14. A low k dielectric layer having a carbon content of less than about 50 atomic weight percent formed by the method comprising:
providing a substrate having a surface;
applying an asymmetric organocyclosiloxane compound along with at least one compound selected to reduce the carbon content of said dielectric layer, to said substrate surface; and
reacting said organocyclosiloxane compound with said substrate surface and depositing said dielectric layer on said substrate surface;
wherein said dielectric layer has a carbon content less than about 50 atomic weight percent.

15. The method according to claim 14, wherein said at least one compound is an oxidizing agent.

16. The method according to claim 15, wherein said oxidizing agent is selected from the group consisting of O₂, O₃, N₂O, and H₂O₂.

17. The method according to claim 14, wherein said at least one compound is a silicon containing compound.

18. The method according to claim 17, wherein said silicon containing compound is selected from the group consisting of SiH₄; MeSiH₃; MeSi(OMe)₃; Me₂Si(OEt)₂; Me₃Si(OEt); vinylSiMe₃; vinylSiMe₂H; vinylSiMeH₂; vinylSi(OMe)₃; hexamethylcyclotrisiloxane; trimethylcyclotrisiloxane; octamethylcyclotetrasiloxane; tetramethylcyclotetrasiloxane; 1,3-divinyl-1,3,5-trimethylcyclotrisiloxane and 1,1-divinyl-3,3,5,5-tetramethylcyclotrisiloxane.

19. The method according to claim 14, wherein said carbon content of said dielectric layer is in the range of 15 to 25 atomic weight percent.

20. The method according to claim 14, wherein said at least one compound comprises an oxidizing agent and a silicon containing compound.

21. The method according to claim 14, wherein said organocyclosiloxane has the chemical formula (—SiO—)ₙR₍₂ₙ₋ₘ₎R′ₘ where (—SiO—) is a cyclic siloxane ring; n is at least 3; R is an alkyl containing hydrocarbon from C1 to C7; R′ is a member selected from the group consisting of H, a vinyl group, and a cyclohexyl group; and m is at least 1.
